(19) United States
(12) Patent Application Publication
(10) Pub. No.: US 2025/0072255 A1
(43) Pub. Date: Feb. 27, 2025

(54) DISPLAY DEVICE AND MANUFACTURING METHOD THEREOF

(71) Applicant: Samsung Display Co., Ltd., Yongin-Si (KR)

(72) Inventors: Ho-Yong SHIN, Yongin-si (KR); Seon Uk LEE, Yongin-si (KR); Che Ho LIM, Yongin-si (KR)

(21) Appl. No.: 18/582,666

(22) Filed: Feb. 21, 2024

(30) Foreign Application Priority Data
Aug. 21, 2023 (KR) 10-2023-0108939

(51) Int. Cl. H10K 59/38; H10K 59/12; H10K 59/122

(52) U.S. Cl. CPC H10K 59/38; H10K 59/1201; H10K 59/122

(57) ABSTRACT

A display device according to an embodiment includes a display unit having a plurality of light emitting regions, a non-light emitting region positioned between the adjacent light emitting regions, and a color conversion unit overlapping the display unit and including a bank layer and a spacer, the bank layer has an opening corresponding to the light emitting region and a bank hole corresponding to the non-light emitting region, the bank hole overlapping the spacer on a plane, and at least a portion of an edge of the bank layer around the bank hole includes a low liquid repellent portion having a lower liquid repellency than a remaining surface of the bank layer.

### CROSS-REFERENCE TO RELATED APPLICATION

This application claims priority to and the benefit of Korean Patent Application No. 10-2023-0108939 filed at the Korean Intellectual Property Office on Aug. 21, 2023, the entire contents of which are incorporated herein by reference.

### BACKGROUND

### (a) Technical Field

The present disclosure relates to a display device and a manufacturing method.

### (b) Description of the Related Art

An organic light emitting device (OLED) is a device that forms an exciton when a positive hole supplied from an anode and an electron supplied from a cathode combine within the light emitting layer disposed between the anode and cathode. As this exciton stabilizes, light is emitted.

Since the light emitting device offers various desirable characteristics such as a wide viewing angle, fast response speed, thinness, and low power consumption, it is widely applied to various electric and electronic devices such as televisions, monitors, and mobile phones.

Recently, a display device including a color conversion layer has been proposed to implement a high-efficiency display device.

The color conversion layer may convert incident light into a different color.

### SUMMARY

Embodiments are intended to prevent display defects caused by penetration of impurities such as moisture into the display device through defects in a layer of the display device.

A display device according to an embodiment includes a display unit having a plurality of light emitting regions, a non-light emitting region positioned between adjacent light emitting regions, and a color conversion unit overlapping the display unit and including a bank layer and a spacer, the bank layer has an opening corresponding to the light emitting region and a bank hole corresponding to the non-light emitting region, the bank hole overlapping the spacer on a plane, and at least a portion of an edge of the bank layer around the bank hole includes a low liquid repellent portion having a lower liquid repellency than a remaining surface of the bank layer.

The low liquid repellent portion may be formed along a periphery of the bank hole.

A color conversion layer may be positioned in the opening, and a material layer having a material included in the color conversion layer may be positioned in the bank hole.

A thickness of the material layer may be smaller than a thickness of the color conversion layer.

The material layer may include semiconductor nanocrystals.

The display unit includes a pixel insulating layer having a pixel opening defining the light emitting region and overlapping the non-light emitting region, and the color conversion unit includes a substrate and a plurality of color filters positioned between the substrate and the bank layer.

The spacer may include a portion located inside the bank hole and a portion located outside the bank hole and covering the bank hole.

The bank layer may further include a filling layer positioned between the spacer and the plurality of color filters and positioned between the bank layer and the display unit.

The spacer may be spaced apart from the above bank hole.

The spacer may further include a filling layer positioned between the bank layer and the plurality of color filters, and positioned between the bank layer and the plurality of color filters.

The display unit may further include a light emitting device and an encapsulation part covering the light emitting device, and the bank layer may be formed on the encapsulation part.

The low liquid repellent portion may form an inclined surface or a concave portion along a peripheral surface of the bank layer.

The bank hole may have a long side and a short side shorter than the long side on a plane, and a length of the short side of the bank hole may be smaller than a radius of the spacer overlapping the bank hole.

A display device according to an embodiment includes a display unit having a plurality of light emitting regions, a non-light emitting region positioned between the adjacent light emitting regions, and a color conversion unit overlapping the display unit and including a bank layer and a spacer, the bank layer has an opening corresponding to the light emitting region and a bank hole corresponding to the non-light emitting region, the bank hole overlapping the spacer on a plane, and the bank hole having a long side and a short side shorter than the long side on a plane, wherein a length of the short side of the bank hole is smaller than a radius of the spacer overlapping the bank hole.

A length of the long side of the bank hole may be longer than a diameter of the overlapping spacer.

An edge of the bank layer around the bank hole may include a low liquid repellent portion having a lower liquid repellency than a remaining surface of the bank layer.

The low liquid repellent portion may be formed along the periphery of the bank hole. The low liquid repellent portion may form a closed loop in plan view.

A method of manufacturing a display device according to an embodiment includes forming a bank layer having a plurality of openings and a plurality of bank holes by stacking and patterning an organic material layer on a substrate, a color conversion layer and a transmission layer in the plurality of openings, and forming a spacer overlapping the bank hole, wherein the forming of the bank layer comprises forming a low liquid repellent portion on an edge of the bank layer around the bank hole having a lower liquid repellency than a remaining surface of the bank layer.

The forming of the bank layer may comprise a first portion corresponding to the bank hole, a second portion having transmittance opposite to that of the first portion, and a second portion disposed between the first portion and the second portion and having transmissivity, and the method may include exposing the bank layer through an exposure mask having a third portion.

The third portion may comprise a translucent portion or a slit.

According to the embodiments, it is possible to prevent display defects from occurring by preventing impurities such as moisture from penetrating into the display device by blocking defects in a layer of the display device.

### BRIEF DESCRIPTION OF THE DRAWINGS

FIG. 1 is a plan view of a display device according to an embodiment.

FIG. 2 is a cross-sectional view of a display device according to an embodiment.

FIG. 3 is a plan view of a display area of a display device according to an embodiment.

FIG. 4 is a plan view of a display area of a display device according to an embodiment.

FIG. 5 is a cross-sectional view of the display device shown in FIG. 4 taken along line A1-A2.

FIG. 6 is a cross-sectional view of the display device shown in FIG. 4 taken along line A1-A2.

FIG. 7 is a cross-sectional view of a display device according to a comparative example.

FIG. 8 to FIG. 11 are cross-sectional views of a display device for each process of a manufacturing method of a display device according to an embodiment.

FIG. 12 is a plan view of a bank of a display device according to an embodiment.

FIG. 13 and FIG. 14 are cross-sectional views of a bank of the display device shown in FIG. 12 taken along line C1-C2.

FIG. 15 is a cross-sectional view of a photomask used in a process of forming a bank of a display device according to an embodiment.

FIG. 16 is a cross-sectional view of a photomask used in a process of forming a bank of a display device according to an embodiment.

FIG. 17 is a cross-sectional view of a photomask according to an embodiment.

FIG. 18 is a cross-sectional view of the photomask shown in FIG. 17 cut along line B1-B2.

FIG. 19 is a photograph taken from above of ink dripping on a bank exposed using the photomask shown in FIGS. 17 and 18.

FIG. 20 is a photograph taken from above of ink dropped on a bank exposed to full tone.

FIG. 21 is a perspective view of a bank hole of a display device according to an embodiment.

FIG. 22 is a plan view illustrating a relationship between a bank hole and a space of a display device according to an embodiment.

FIG. 23 and FIG. 24 are plan views illustrating a relationship between a bank hole and a space of a display device according to an embodiment.

### DETAILED DESCRIPTION OF THE EMBODIMENTS

Hereinafter, with reference to the accompanying drawings, various embodiments of the present inventive concepts will be described in detail so that those skilled in the art can easily carry out the present inventive concept.

This disclosure may be embodied in many different forms and is not limited to the embodiments set forth herein.

In order to clearly describe the present inventive disclosure, parts irrelevant to the description are omitted, and the same reference numerals are assigned to the same or similar components throughout the specification.

In addition, since the size and thickness of each component shown in the drawings are arbitrarily shown for convenience of explanation, the present invention is not necessarily limited to that which is shown.

In the drawings, the thickness is shown enlarged to clearly express the various layers and regions.

And in the drawings, for convenience of explanation, the thicknesses of some layers and regions are exaggerated.

In addition, when a part such as a layer, film, region, or plate is said to be “above” or “on” another part, this includes not only the case where it is “directly on” the other part, but also the case where another part exists in the middle thereof.

Conversely, when a part is said to be “directly on” another part, it means that there is no other part in between.

In addition, being “above” or “on” a reference part means being located above or below the reference part, and does not necessarily mean being located “above” or “on” in the opposite direction of gravity.

In addition, throughout the specification, when a certain component is said to “include,” it means that it may further include other components without excluding other components unless otherwise stated.

In addition, throughout the specification, when it is referred to as a “planar image,” it means when the target part is viewed from above, and when it is referred to a “cross-sectional image,” it means when a cross-section of the target part cut vertically is viewed from the side.

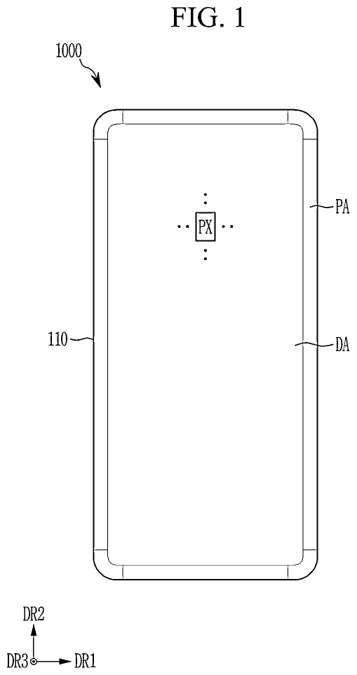

A structure of a display device according to an embodiment will be described with reference to FIGS. 1 to 4.

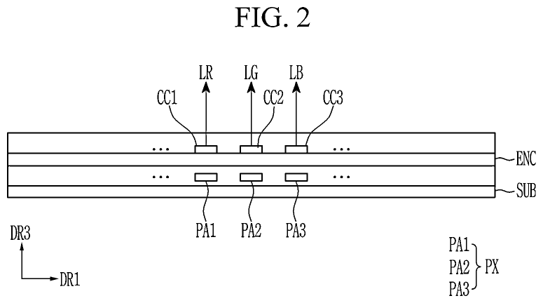

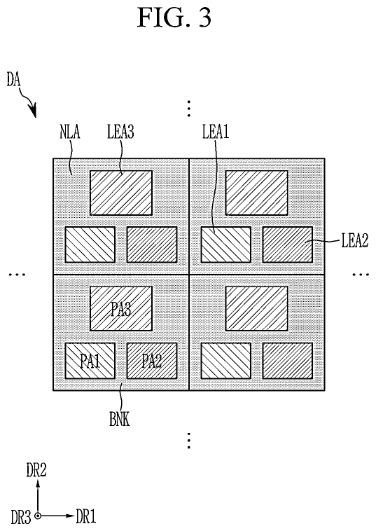

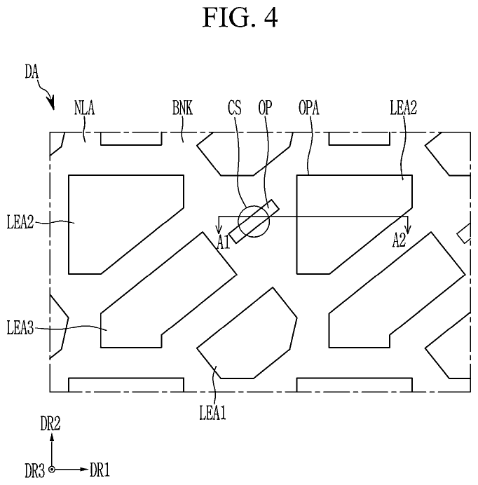

FIG. 1 is a plan view of a display device according to an embodiment, FIG. 2 is a cross-sectional view of the display device according to an embodiment, FIG. 3 is a plan view of a display area of the display device according to an embodiment, and FIG. 4 is a plan view of a display device according to an embodiment, and it is a plan view of the display area of the display device according to the example.

Referring to FIG. 1, a display device 1000 according to an embodiment includes a display panel 110 including a display area DA capable of displaying an image and a peripheral area PA around the display area DA.

The display area DA includes a plurality of pixels PX as a unit for displaying an image, and the peripheral area PA may or may not display an image.

The peripheral area PA may surround the display area DA, but is not limited thereto.

The display area DA may have a display surface parallel to a plane defined by the first and second directions DR1 and DR2.

A direction that is normal to the plane of the display surface on which an image is displayed is herein referred to as a thickness direction of the display panel 110, and may be parallel to the third direction DR3.

The display panel 110 may be a rigid display panel, but is not limited thereto and may also be a flexible display panel.

The display panel 110 may be a light emitting display panel, but the type of display panel 110 is not limited thereto and may be various types of panels.

For example, the display panel 110 may include a micro light emitting diode display panel, a quantum dot light emitting diode display panel, a quantum dot organic light emitting diode display panel, and the like.

Referring to FIGS. 1 and 2, the display panel 110 according to an embodiment includes at least one substrate SUB, and a plurality of pixels are provided on the substrate SUB corresponding to the display area DA of FIG. 1.

The plurality of pixels PX may include a first pixel PA1, a second pixel PA2, and a third pixel PA3 capable of representing different colors.

Each pixel PX may include at least one transistor and a light emitting device connected thereto.

An encapsulation unit ENC may be positioned on the plurality of pixels PX.

The encapsulation ENC may cover the light emitting device ED to protect the light emitting device ED from external air or moisture.

The encapsulation ENC may overlap the front surface of the display area DA in a direction in which an image is displayed, and may also be partially disposed on the peripheral area PA.

A first color conversion part CC1, a second color conversion part CC2, and a transmission part CC3 may be positioned on the encapsulation part ENC.

The first color conversion part CC1 overlaps the first pixel PA1, the second color conversion part CC2 overlaps the second pixel PA2, and the transmission part CC3 overlaps the third pixel PA3.

Light emitted from the first pixel PA1 may pass through the first color conversion unit CC1 to provide first color light LR.

Light emitted from the second pixel PA2 may pass through the second color conversion unit CC2 to provide second color light LG.

Light emitted from the third pixel PA3 may pass through the transmission part CC3 to provide the third color light LB.

In one embodiment, the first color light LR may be red light, the second color light LG may be green light, and the third color light LB may be blue light, but the displayed colors are not limited thereto.

Referring to FIGS. 2, 3, and 4, the display area DA according to an embodiment may include a plurality of light emitting regions corresponding to a plurality of pixels PX.

For example, the first light emitting region LEA1 corresponding to the first pixel PA1, the second light emitting region LEA2 corresponding to the second pixel PA2, and the third light emitting region LEA3 corresponding to the third pixel PA3 may be included.

In the display area DA, a non-light emitting region NLA may be positioned between the first light emitting region LEA1, the second light emitting region LEA2, and the third light emitting region LEA3.

Each of the light emitting regions LEA1, LEA2, and LEA3 is illustrated as a rectangle on a plane, but may have other shapes such as a rhombus, a pentagon, and an octagon, and may have various shapes and areas according to embodiments.

A bank layer BNK may be positioned in the non-light emitting region NLA, and the opening OPA may be formed by removing the bank layer BNK from each of the light emitting regions LEA1, LEA2, and LEA3.

The bank layer BNK may include an organic material such as acrylic resin.

The bank layer BNK may include a light absorbing material that absorbs a visible light wavelength band.

According to an embodiment, the bank layer BNK may serve as a light blocking member by including an organic light blocking material and may serve as a barrier rib.

Referring to FIG. 4, a bank layer BNK included in a display device according to an embodiment may have a plurality of bank holes OP positioned in a non-light emitting region NLA.

Each bank hole OP may overlap a corresponding spacer CS on a plane.

The bank hole OP does not overlap the light emitting regions LEA1, LEA2, and LEA3 of each pixel.

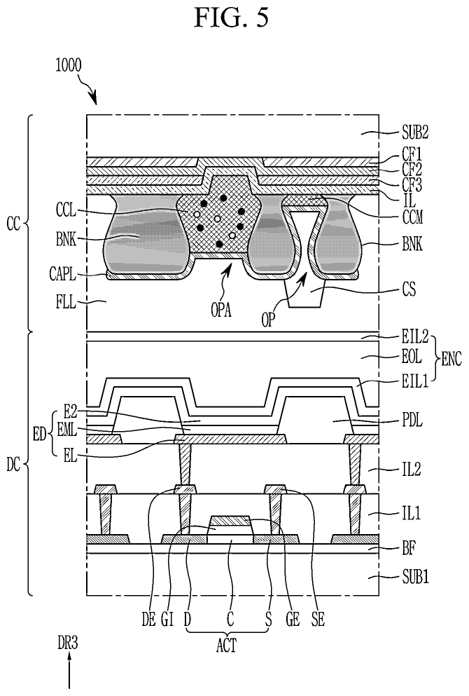

A detailed cross-sectional structure of the display device according to the embodiment will be described with reference to FIGS. 5 to 7 along with the previously described drawings.

FIG. 5 is a cross-sectional view of the display device shown in FIG. 4 taken along the line A1-A2.

Referring to FIG. 5, a display device 1000 according to an embodiment may include a display unit DC and a color conversion unit CC.

The display unit DC may include a first substrate SUB1 and a plurality of transistors and a plurality of light emitting devices formed thereon.

The first substrate SUB1 may include an insulating material and may include a transparent material.

For example, the first substrate SUB1 may include glass, quartz, or plastic such as polyimide.

The first substrate SUB1 may be a rigid substrate or may have a flexible characteristic capable of being bent, folded, or rolled.

A buffer layer BF may be positioned on the first substrate SUB1.

The buffer layer BF may include an inorganic insulating material or an organic insulating material including a silicon oxide (SiOₓ), a silicon nitride (SiNₓ), and a silicon oxynitride (SiOₓN_{y}), and may have a single layer or multiple layers.

A semiconductor layer ACT may be positioned on the buffer layer BF.

The semiconductor layer ACT may include a semiconductor material such as amorphous silicon, polycrystalline silicon, or an oxide semiconductor.

The semiconductor layer ACT may include a channel region C, a source region S, and a drain region D.

The source region S and the drain region D may be disposed on both sides of the channel region C, respectively.

The channel region C is an intrinsic semiconductor not doped with impurities, and the source region S and the drain region D are impurity semiconductors doped with conductive impurities and may have conductivity.

A gate insulating layer GI may be positioned on the semiconductor layer ACT.

The gate insulating layer GI may include an inorganic insulating material or an organic insulating material including a silicon oxide (SiOₓ), a silicon nitride (SiNₓ), and a silicon oxynitride (SiOₓN_{y}), and may have a single layer or multiple layers.

A first conductive layer including a gate electrode GE may be positioned on the gate insulating layer GI.

The first conductive layer is aluminum (Al), platinum (Pt), palladium (Pd), silver (Ag), magnesium (Mg), gold (Au), nickel (Ni), neodymium (Nd), or iridium (Ir), it may include at least one metal or metal alloy such as chromium (Cr), nickel (Ni), calcium (Ca), molybdenum (Mo), titanium (Ti), tungsten (W), copper (Cu), and it may consist of a single layer or multiple layers.

An interlayer insulating layer IL1 may be positioned on the gate electrode GE.

The interlayer insulating layer IL1 may include an inorganic insulating material or an organic insulating material including a silicon oxide (SiOₓ), a silicon nitride (SiNₓ), and a silicon nitride oxide (SiOₓN_{y}), and may have a single layer or multiple layers.

A second conductive layer including a source electrode SE and a drain electrode DE may be positioned on the interlayer insulating layer IL1.

The source electrode SE and the drain electrode DE may be electrically connected to the source region S and the drain region D of the semiconductor layer ACT through contact holes formed in the interlayer insulating layer IL1, respectively.

A passivation layer IL2 may be positioned on the interlayer insulating layer IL1, the source electrode SE, and the drain electrode DE.

The passivation layer IL2 may cover and planarize the interlayer insulating layer IL1, the source electrode SE, and the drain electrode DE.

The passivation layer IL2 may include organic insulating materials or inorganic insulating materials such as polymer derivatives, acrylic polymers, imide polymers, polyimides, polyamides, acrylic polymers, and siloxane polymers.

A third conductive layer including the first electrode E1 may be positioned on the passivation layer IL2.

The first electrode E1 may be electrically connected to the drain electrode DE through the contact hole of the passivation layer IL2.

A driving transistor composed of a gate electrode GE, a semiconductor layer ACT, a source electrode SE, and a drain electrode DE is electrically connected to the first electrode E1 to apply driving current to the light emitting device ED, which will be described later.

The display device according to the embodiment may further include a switching transistor connected to a data line and responding to a scan signal to transmit a data voltage, and a compensation transistor connected to a driving transistor and responding to a scan signal to compensate for the threshold voltage of the driving transistor, in addition to the driving transistor.

A pixel insulating layer PDL may be positioned on the passivation layer IL2 and the first electrode E1.

The pixel insulating layer PDL may have a pixel opening overlapping the first electrode E1 and defining an light emitting region.

The pixel insulating layer PDL may include an organic insulating material such as polyimide, polyamide, acrylic resin, benzocyclobutene, or phenol resin, or a silica-based inorganic insulating material.

An emission layer EML may be positioned on the first electrode E1 overlapping the pixel opening.

The light emitting layer EML may include a low molecular weight organic material or a high molecular weight organic material such as poly(3,4-ethylene dioxythiophene) (PEDOT).

The light emitting layer EML includes at least one of a hole injection layer (HIL), a hole transporting layer (HTL), an electron transporting layer (ETL), and an electron injection layer (EIL). It may further be a multi-film.

Most of the light emitting layer EML may be positioned within the pixel opening, and may include a portion positioned on or on the side of the pixel insulating layer PDL.

A second electrode E2 may be positioned on the light emitting layer EML.

The second electrode E2 may be formed of a single conductor across the plurality of pixels PX.

The first electrode E1, the light emitting layer EML, and the second electrode E2 may constitute the light emitting device ED.

The first electrode E1 may be an anode that is a hole injection electrode, and the second electrode E2 may be a cathode that is an electron injection electrode.

However, the embodiment is not necessarily limited thereto, and the first electrode E1 may serve as a cathode and the second electrode E2 may serve as an anode according to a driving method of the display device.

Holes and electrons are injected into the light emitting layer EML from the first electrode E1 and the second electrode E2, respectively, and light emission occurs when excitons in which the injected holes and electrons are combined fall from an excited state to a ground state.

An encapsulation unit ENC may be positioned on the second electrode E2.

The encapsulation unit ENC may block the inflow of external moisture and oxygen by covering and sealing the light emitting device ED.

The encapsulation unit ENC may include a plurality of layers and may be formed of a composite layer including an inorganic layer and an organic layer that are alternately stacked.

For example, the encapsulation portion ENC may include an inorganic layer EIL1, an organic layer EOL, and an inorganic layer EIL2 sequentially formed.

A color conversion unit CC may be positioned on the encapsulation unit ENC.

The color conversion unit CC may include a second substrate SUB2 overlapping and parallel to the first substrate SUB1.

The second substrate SUB2 may include an insulating material and may include a transparent material.

For example, the first substrate SUB1 may include glass, quartz, or a plastic such as polyimide.

The first substrate SUB1 may be a rigid substrate or may have a flexible characteristic capable of being bent, folded, or rolled.

The color conversion unit CC may include a first color filter CF1, a second color filter CF2, and a third color filter CF3 positioned between the second substrate SUB2 and the display unit DC.

According to an embodiment, the first color filter CF1, the second color filter CF2, and the third color filter CF3 may be formed below the lower surface of the second substrate SUB2.

The first color filter CF1 may overlap the color conversion layer CCL corresponding to the first light emitting region LEA1.

The first color filter CF1 transmits the first color light that has passed through the color conversion layer CCL corresponding to the first light emitting region LEA1 and absorbs light of other wavelengths, thereby emitting light to the outside of the display device, such that the purity of the first color light can be increased.

The second color filter CF2 may overlap the color conversion layer CCL corresponding to the second light emitting region LEA2.

The second color filter CF2 transmits the second color light that has passed through the color conversion layer CCL corresponding to the second light emitting region LEA2 and absorbs light of other wavelengths, thereby emitting light to the outside of the display device such that the purity of the second color light can be increased.

The third color filter CF3 may overlap the transmission layer corresponding to the third light emitting region LEA3.

The third color filter CF3 transmits the third color light that has passed through the transmission layer corresponding to the third light emitting region LEA3 and absorbs light of the remaining wavelengths, thereby generating the third color light emitted to the outside of the display device such that the purity of the third color light can be increased.

At least two of the first color filter CF1, the second color filter CF2, and the third color filter CF3 may overlap in the non-light emitting region NLA to serve as a light blocking member.

The non-light emitting region NLA may overlap the pixel insulating layer PDL of the display unit DC.

An insulating layer IL may be positioned between the first color filter CF1, the second color filter CF2, and the third color filter CF3 and the display unit DC.

The insulating layer IL may include an inorganic insulating material or an organic insulating material including a silicon oxide (SiOₓ), a silicon nitride (SiNₓ), and a silicon oxynitride (SiOₓN_{y}).

The insulating layer IL may be stacked under the lower surfaces of the first color filter CF1, the second color filter CF2, and the third color filter CF3.

A bank layer BNK may be positioned between the insulating layer IL and the display DC.

The bank layer BNK may have an opening OPA that is aligned with the pixel opening.

The opening OPA may define light emitting regions LEA1, LEA2, and LEA3 of each pixel.

The bank layer BNK may overlap the pixel insulating layer PDL of the display unit DC.

In the opening OPA, a color conversion layer CCL corresponding to the first light emitting region LEA1, a color conversion layer CCL corresponding to the second light emitting region LEA2, and a color conversion layer CCL corresponding to the third light emitting region LEA3, a transmissive layer may be present.

According to one embodiment, the bank layer BNK may be formed under the lower surface of the insulating layer IL.

The color conversion layer CCL may convert incident light into a first color or a second color.

The color conversion layer CCL may include quantum dots.

In this specification, quantum dots (also referred to as semiconductor nanocrystals) can include group II-VI compounds, group III-V compounds, group IV-VI compounds, group IV elements or compounds, group I-III-VI compounds, group II-III-VI compounds, group I-II-IV-VI group compounds, or a combination thereof.

According to embodiments, quantum dots may have a core-shell structure including a core including nanocrystals and a shell surrounding the core.

The shell of the quantum dots may serve as a protective layer for maintaining semiconductor properties by preventing chemical denaturation of the core and/or as a charging layer for imparting electrophoretic properties to the quantum dots.

The shell may have a monolayer or a multilayer structure.

The interface between the core and the shell may have a concentration gradient in which the concentration of elements present in the shell decreases with distance to the center of the quantum dot.

Examples of the quantum dot shell include oxides of metals or non-metals, semiconductor compounds, or combinations thereof.

The interface between the core and the shell may have a concentration gradient in which the concentration of elements present in the shell decreases with distance to the center.

The semiconductor nanocrystal may have a structure including a single semiconductor nanocrystal core and a multi-layered shell surrounding the core.

Quantum dots can control the absorption/emission wavelength by controlling the composition and size.

The maximum emission peak wavelength of the quantum dots may have a wavelength range of ultraviolet to infrared wavelengths or higher.

The transmission layer may include a scattering material and may transmit light incident from the light emitting device ED.

The color conversion layer CCL corresponding to the first light emitting region LEA1 may color-convert incident light into a first color and emit it.

The color conversion layer CCL corresponding to the second light emitting region LEA2 may color-convert incident light into a second color and emit it.

Light incident to the transmission layer corresponding to the third light emitting region LEA3 may be transmitted without color change.

The incident light may include, for example, blue light.

In this case, the incident light may be blue light alone or a mixture of blue light and green light.

Alternatively, blue light, green light, and red light may all be included in incident light.

A filling layer FLL may be positioned between the color conversion layer CCL and the display DC.

The filling layer FLL may couple the color conversion part CC and the display part DC to each other by functioning as an adhesive.

The filling layer FLL may include a filler.

Depending on the embodiment, air may be filled in the position of the filling layer FLL.

A spacer CS may be positioned between the bank layer BNK and the encapsulation ENC.

The spacer CS may be directly formed on the encapsulation portion ENC (that embodiment is not shown) or may be directly formed under the bank layer BNK as shown in FIG. 5.

In the embodiment of FIG. 5, the spacer CS may be positioned between the bank layer BNK and the filling layer FLL.

The spacer CS may maintain a gap between the display unit DC and the color conversion unit CC.

The bank layer BNK according to an embodiment may have a plurality of bank holes OP spaced apart from the opening OPA.

The bank hole OP may be filled with the planar spacer CS.

The spacer CS overlapping the bank hole OP may include a portion located inside the bank hole OP and a portion located outside the bank hole OP and overlapping the bank hole OP on the bank hole OP.

The bank hole OP and the spacer CS may overlap the pixel insulating layer PDL.

Referring to FIG. 5, a material layer CCM having a material included in the color conversion layer CCL may be present in any one of the plurality of bank holes OP.

However, this is not a limitation of the disclosure, and the material layer CCM may be disposed outside of the bank hole OP in some embodiments.

In cases where a material layer CCM is disposed in the bank hole OP, the thickness of the third direction DR3 of the material layer CCM may be less than the thickness of the third direction DR3 of the color conversion layer CCL located within the opening OPA.

At least a portion of an edge of the bank layer BNK around the bank hole OP may include a low liquid repellent portion having lower liquid repellency than surfaces of other bank layers BNK.

The low liquid repellent portion may be formed in a closed curve shape along the periphery of the bank hole OP, but is not limited thereto.

A capping layer CAPL may be positioned between the bank layer BNK, the color conversion layer CCL, the transmission layer and the material layer CCM, the filling layer FLL, and the spacer CS.

The capping layer CAPL may cover the bank layer BNK, the color conversion layer CCL, the transmission layer, and the material layer CCM.

At least a portion of the capping layer CAPL may be positioned on inner walls of the bank hole OP and the opening OPA.

The capping layer CAPL can prevent impurities such as moisture or air from penetrating into the first color filter CF1, the second color filter CF2, the third color filter CF3, the color conversion layer CCL, and the transmission layer.

The capping layer CAPL may include an inorganic material.

The filling layer FLL may be positioned between the bank layer BNK, the color conversion layer CCL, the transmission layer, the material layer CCM, and the capping layer CAPL, and the encapsulation ENC of the display unit DC.

The capping layer CAPL may include a portion positioned between the bank layer BNK and the spacer CS.

Among the bank holes OP, the inside of the bank hole OP not filled with the spacer CS may be filled with the filling layer FLL.

According to one embodiment, the bank hole OP may be formed to completely penetrate the bank layer BNK in the third direction DR3 to the bottom of the insulating layer IL, and may partially penetrate the bank layer BNK in the third direction DR3 so that a portion of the bank layer BNK may remain where the bank hole OP is located.

That is, the thickness of the bank hole OP in the third direction DR3 may be the same as or similar to the thickness of the bank layer BNK in which the bank hole OP or the opening OPA is not formed in the third direction DR3, and it may or may not be small.

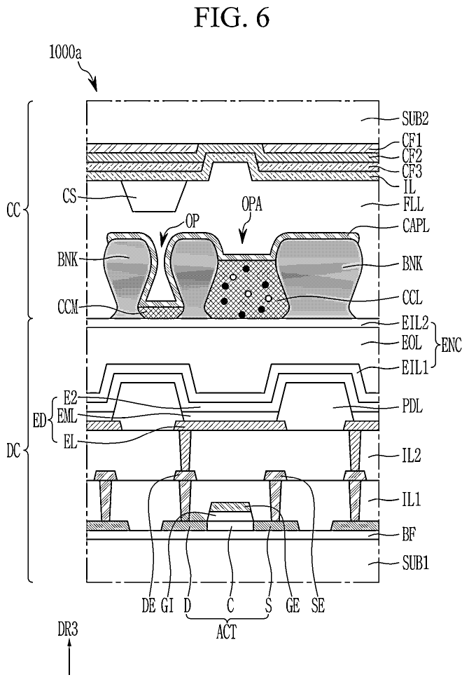

FIG. 6 is a cross-sectional view of the display device shown in FIG. 4 taken along the line A1-A2.

Referring to FIG. 6, a display device 1000a according to an embodiment is substantially the same as the display device 1000 according to the aforementioned embodiment, but includes a bank layer BNK, a color conversion layer CCL, a transmission layer, and materials, and the layer CCM may be formed on the encapsulation part ENC of the display part DC.

The filling layer FLL may be positioned between the bank layer BNK, the color conversion layer CCL, the transmission layer, the material layer CCM, the capping layer CAPL, and the insulating layer IL.

The spacer CS may be positioned between the insulating layer IL and the filling layer FLL.

The spacer CS may be formed on the lower surface of the second substrate SUB2.

The bank hole OP of the bank layer BNK may overlap and face the spacer CS on a plane.

The spacer CS overlapping the bank hole OP may be spaced apart from the bank layer BNK in the third direction DR3 or may contact the upper surface of the bank layer BNK or the upper surface of the capping layer CAPL.

Depending on the embodiment, a part of the spacer CS may be positioned inside the bank hole OP of the bank layer BNK.

The bank hole OP and the spacer CS may overlap the pixel insulating layer PDL.

The filling layer FLL may be positioned between the first color filter CF1, the second color filter CF2, and the third color filter CF3 and the bank layer BNK.

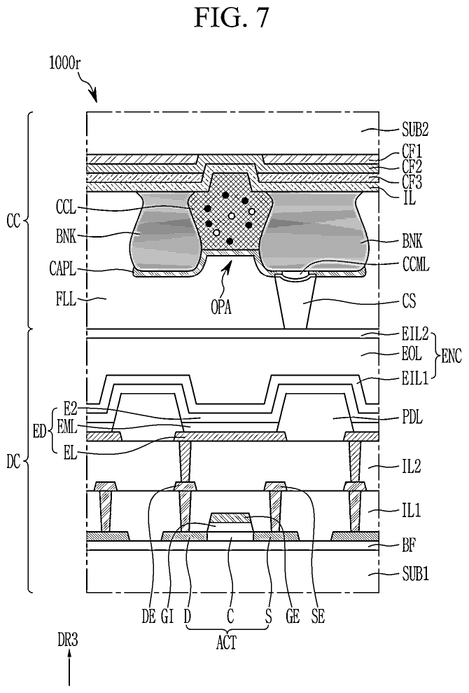

FIG. 7 is a cross-sectional view of a display device according to a comparative example.

During the manufacturing process of the display devices 1000 and 1000a according to the embodiment, the color conversion layer CCL may be formed by, for example, an inkjet printing method.

In the inkjet printing process, the ink for forming the color conversion layer CCL may erroneously land on an area other than the opening OPA instead of being settled on the opening OPA.

Since the display device 1000r according to the comparative example shown in FIG. 7 does not include the bank hole OP, if ink is misplaced on the surface of the bank layer BNK where the spacer CS is located, the ink layer CCML forms on an incorrect position on the layer BNK. As the spacer CS forms on the mis-positioned ink layer CCML, that the height of the spacer CS may become abnormally high.

The spacer CS being too high may cause the end of the spacer CS to come into contact with the encapsulation ENC of the display unit DC, and defects such as cracks may occur in the encapsulation ENC pressed by the spacer CS. Moisture and impurities such as outside air may permeate into the light emitting device ED through the cracks, resulting in display defects.

According to the disclosure, even if ink for forming a color conversion layer CCL is mis-positioned, the mis-positioned ink does not cause the spacer CS to become too high and possibly damage the encapsulation ENC because the ink can flow into the bank hole OP of the bank layer BNK.

Accordingly, defects in the encapsulation ENC may be prevented, and defects in the light emitting device ED and display defects may be prevented.

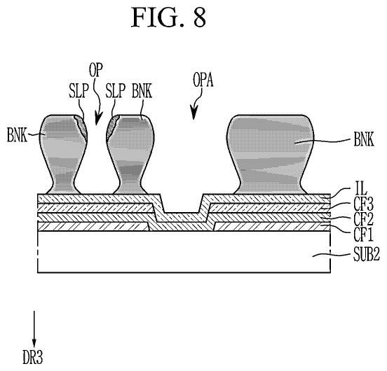

A manufacturing method of a display device according to an embodiment will be described with reference to FIGS. 8 to 11 together with the previously described drawings.

FIG. 8 to FIG. 11 are cross-sectional views of a display device in each process of a manufacturing method of a display device according to an embodiment.

Referring to FIG. 8, a first color filter CF1, a second color filter CF2, and a third color filter CF3 are formed on one surface of the second substrate SUB2.

The first color filter CF1, the second color filter CF2, and the third color filter CF3 may be formed through exposure and development after applying a photosensitive organic material containing a color material of a specific color.

Subsequently, an insulating layer IL is stacked on the first color filter CF1, the second color filter CF2, and the third color filter CF3, and a bank layer BNK is formed thereon.

The bank layer BNK may include a photosensitive organic material.

The bank layer BNK patterned by exposing and developing the bank layer BNK may have a plurality of openings OPA and a plurality of bank holes OP.

At least a part of the edge of the bank layer BNK around the bank hole OP may include a low liquid repellent portion SLP having a lower liquid repellency than the remaining portion of the surface of the bank layer BNK (the portion not indicated as SLP).

The low liquid repellent portion SLP may be formed using a semitransmissive portion of an exposure mask used in a patterning process of the bank layer BNK.

The low liquid repellent portion SLP may be formed along the periphery of the bank hole OP, sometimes in a closed loop shape, but is not limited thereto.

A specific method of forming the low liquid repellent portion SLP will be described later.

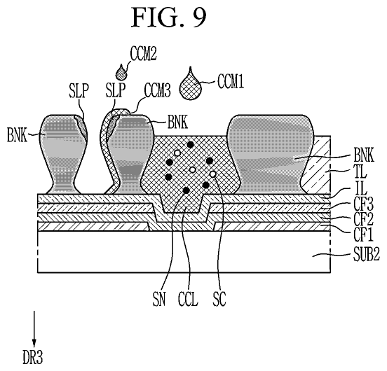

Next, referring to FIG. 9, a color conversion layer CCL and a transmission layer are formed in the plurality of openings OPA defined in the bank layer BNK.

The color conversion layer CCL may be formed by an inkjet printing process using an ink composition.

The color conversion layer CCL and the transmission layer corresponding to the light emitting regions LEA1, LEA2, and LEA2 exhibiting different colors may be formed of different ink compositions.

The ink composition of the color conversion layer CCL may include scatterers SC and quantum dots SN, and the transmission layer may include scatterers.

The ink CCM1 dropped toward the opening OPA of the bank layer BNK may settle in the opening OPA to form the color conversion layer CCL, but some ink CCM1 may fall into the bank hole OP where the spacer is to be located. The dripping ink CCM2 may enter the bank hole OP. The ink CCM3 on the edge of the bank layer BNK around the bank hole OP may flow into the bank hole OP.

In particular, when the low liquid repellent portion SLP is formed at the edge of the bank layer BNK around the bank hole OP, the ink CCM3 is more likely to flow into the bank hole OP instead of staying around the edge.

Ink entering the bank hole OP may form a material layer CCM.

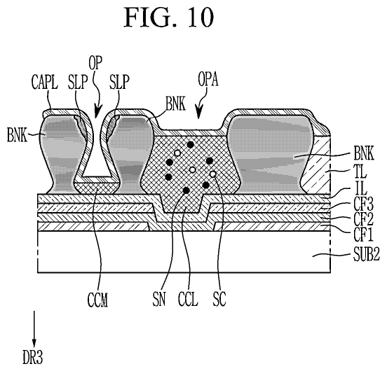

Next, referring to FIG. 10, the capping layer CAPL may be formed by disposing an inorganic material on the bank layer BNK, the material layer CCM, and the color conversion layer CCL.

The capping layer CAPL may be formed over the entire area of the substrate SUB2.

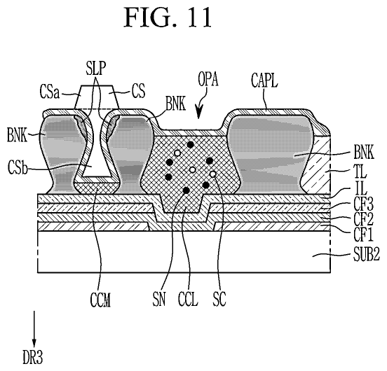

Next, referring to FIG. 11, spacers CS are formed on a portion overlapping the bank hole OP on the bank layer BNK.

The spacer CS may include a portion CSa positioned higher than the upper surface of the bank layer BNK and a portion CSb positioned inside the bank hole OP.

Next, as shown in FIG. 5, the color conversion part CC thus formed may be combined with and attached to the display part with the filling layer FLL interposed therebetween to complete the display device.

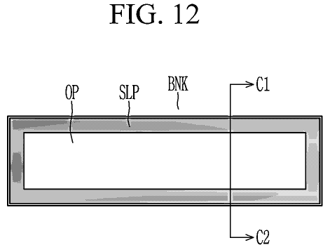

The structure of the low liquid repellent portion SLP of the bank layer BNK around the bank hole OP will be described with reference to FIGS. 12 to 14 together with the previously described drawings.

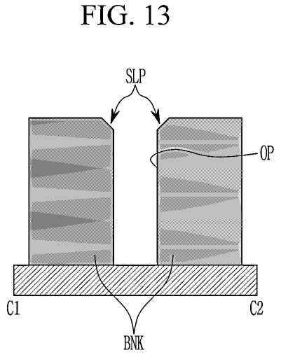

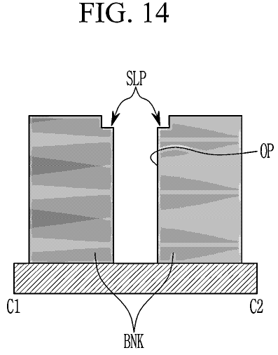

FIG. 12 is a plan view of a bank of a display device according to an embodiment, and FIGS. 13 and 14 are cross-sectional views of the bank of the display device shown in FIG. 12 taken along line C1-C2.

Referring to FIG. 12, at least a portion of an edge of the bank layer BNK around the bank hole OP of a display device according to an embodiment has a low liquid repellent portion SLP having lower liquid repellency than the other portion of the surface of the bank layers BNK.

In a plan view, the low liquid repellent portion SLP may be formed along the periphery of the bank hole OP.

In the embodiment of FIG. 13, the low liquid repellent portion SLP may include a substantially inclined surface sloping down from the upper surface of the bank layer BNK toward the bank hole OP.

In the embodiment of FIG. 14, the low liquid repellent portion SLP may include a cutout or a concave portion at the edge of the bank layer BNK that forms an entrance into the hole OP. The liquid repellent portion SLP may form a step going down into the hole OP from the top surface of the bank layer BNK.

The characteristics of the low liquid repellent portion SLP shown in FIGS. 12 to 24 may also be applied to the display devices 1000 and 1000a according to the embodiments shown in FIGS. 1 to 7 described above.

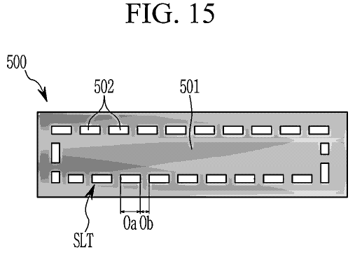

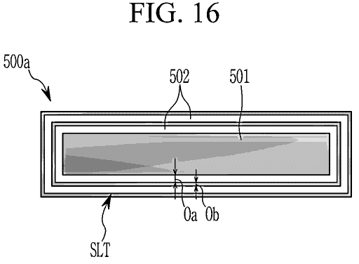

Referring to FIGS. 15 and 16 together with the drawings described above, an exposure mask capable of forming the low liquid repellent portion SLP of the bank layer BNK around the bank hole OP will be described.

FIG. 15 is a cross-sectional view of a photomask used in a process of forming a bank of a display device according to an embodiment, and FIG. 16 is a cross-sectional view of an optical mask used in a process of forming a bank of a display device according to an embodiment.

Referring to FIG. 15, the exposure mask 500 used in the above-described patterning process of the bank layer BNK has a first portion 501 corresponding to the bank hole OP and a second part 502 that has light transmittance characteristics that are opposite of that of the first portion 501. A third part SLT positioned between the first part 501 and the second part 502 may have semi-transmittance.

For example, when the first portion 501 is a light transmitting portion that substantially transmits most of the light, the second portion 502 may be a light blocking portion that blocks light. When the first portion 501 is light blocking, the second portion 502 may be light transmitting.

More specifically, when the photosensitivity of the bank layer BNK is negative, the first portion 501 may be a light blocking portion, the second portion 502 may be a light transmitting portion, and the third portion SLT may be a second portion having lower light transmittance than that of the portion 502 and higher than that of the first portion 501.

The third portion SLT of the exposure mask 500 may include a translucent portion or a slit.

For example, when the light transmittance of the second part 502 is 100%, the light transmittance of the third part SLT may be approximately 50% or more and less than 100%.

When the third portion SLT includes a plurality of slits as shown in FIG. 15, the width Oa of the open portion of the slits may be equal to or larger than the width Ob of the light blocking portion between adjacent open portions, the width Ob of the light blocking portion may be greater than zero.

A plurality of open portions of the slits may be arranged along the circumference of the first portion 501 to form one column or two or more columns.

Each of the width Oa of the open portion and the width Ob of the light blocking portion may be approximately 1 micrometer to 2 micrometers, but is not limited thereto.

Referring to FIG. 16, an exposure mask 500a according to the embodiment is substantially the same as the exposure mask 500 according to the embodiment shown in FIG. 15, but a third part SLT is located around the first part 501 and it may include one or more open portions forming a closed curve band shape.

The width Oa of the open portion may be equal to or greater than the width Ob of the light blocking portion between adjacent open portions, and the width Ob of the light blocking portion may be greater than zero.

Each of the width Oa of the open portion and the width Ob of the light blocking portion may be approximately 1 micrometer to 2 micrometers, but is not limited thereto.

The manufacturing method of the display device according to the embodiment illustrated in FIG. 6 described above may include the manufacturing processes illustrated in FIGS. 8 to 16, but the formation position of the bank layer BNK may be different.

Specifically, a first color filter CF1, a second color filter CF2, and a third color filter CF3, as well as an insulation layer IL, can be stacked on the second substrate SUB2, and a spacer CS can be formed on top of them.

In addition, a bank layer BNK may be formed on the encapsulation portion ENC of the display portion DC and then patterned to form a plurality of openings OPA and a plurality of bank holes OP.

Subsequently, a color conversion layer CCL and a transmission layer may be formed in the plurality of openings OPA defined by the patterned bank layer BNK.

Next, the capping layer CAPL may be formed by stacking an inorganic material on the bank layer BNK, the material layer CCM, and the color conversion layer CCL.

Subsequently, the second substrate SUB2 on which the spacer CS is formed may be bonded to the display portion DC.

In this case, the spacer CS may be positioned where the bank hole OP overlaps.

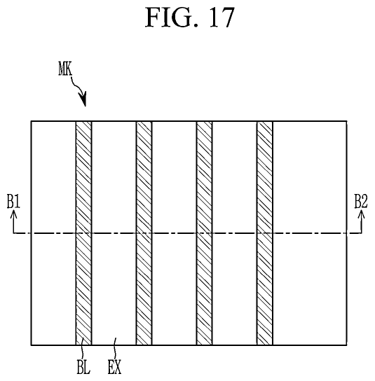

Changes in the liquid repellency of the bank layer according to the exposure method will be described with reference to FIGS. 17 to 20 together with the previously described drawings.

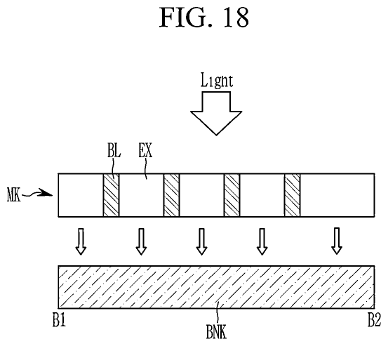

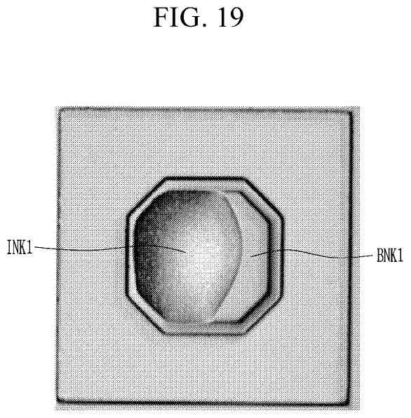

FIG. 17 is a cross-sectional view of a photomask according to an embodiment, FIG. 18 is a cross-sectional view of the photomask shown in FIG. 17 cut along line B1-B2, FIG. 19 is a photomask shown in FIGS. 17 and 18, and FIG. 20 is a photograph taken from above of ink dropped on a bank exposed to a full tone from above.

Referring to FIG. 17 to FIG. 20, an exposure mask MK forms a semi-transmitting portion including open portions EX and light blocking portions BL that are alternately arranged to form a slit, and through the exposure mask MK, light is exposed to the bank layer BNK.

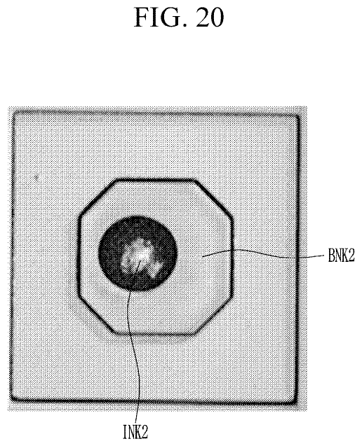

The bank layer BNK exposed through the exposure mask MK forms a bank layer BNK1 (shown in FIG. 19) that has a low liquid repellency on the surface. The bank layer material exposed through 100% of the light-transmitting portion remains to form a bank layer BNK2 (shown in FIG. 20) having higher liquid repellency than the surface of BNK1.

The ink INK2 dropped on the surface of the bank layer BNK2 shown in FIG. 20 hardly spreads due to the relatively high liquid repellency of the bank layer BNK2, but the ink INK2 dropped on the surface of the bank layer spreads further out due to its relatively low liquid repellency.

In accordance with one embodiment, the edge of the bank hole OP of the bank layer BNK of the display device can form a low liquid repellent portion SLP, i.e., a surface of the bank layer BNK with lower foaming than the surrounding area, by undergoing a half-exposure.

Accordingly, the ink that falls on the bank layer BNK around the bank hole OP can spread more easily and flow into the bank hole OP, reducing the probability that misaligned ink will remain on the bank layer BNK.

Accordingly, it is possible to prevent the formation of a spacer CS that is unintentionally tall due to a mispositioned ink, and display defects of the display device can also be prevented.

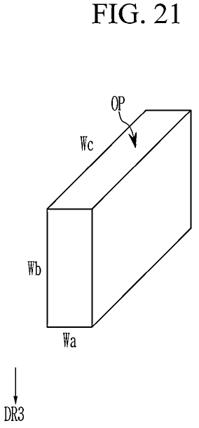

A shape of a bank hole in a bank layer of a display device according to an embodiment and a relationship with a spacer will be described with reference to the aforementioned drawings and FIGS. 21 to 24.

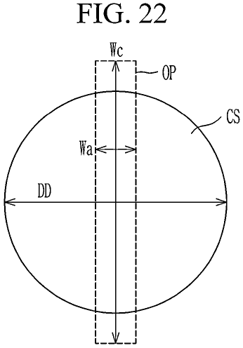

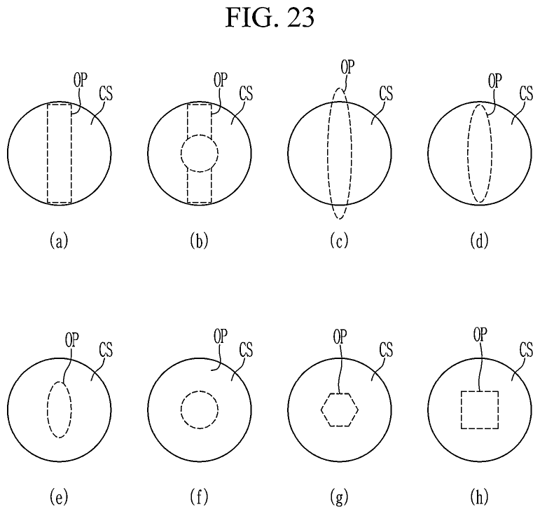

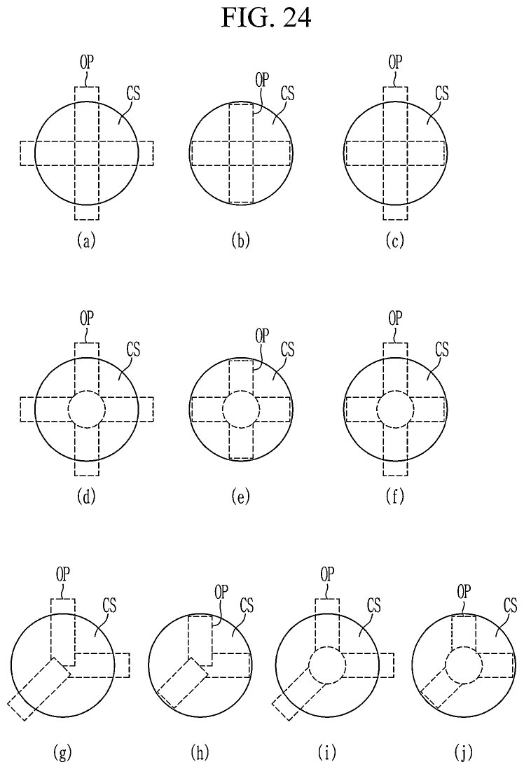

FIG. 21 is a perspective view of a bank hole of a display device according to an embodiment, FIG. 22 is a plan view illustrating a relationship between a bank hole and a space of a display device according to an embodiment, and FIGS. 23 and 24 are displays according to an embodiment, and these are plan views showing the relationship between the bank hole and the space of the device.

Referring to FIG. 21, the volume is controlled by adjusting the short side length Wa, the height Wb, and the long side length Wc of the bank hole OP of the bank layer of the display device according to an embodiment in different directions. The three directions may be mutually orthogonal.

The long side length Wc may be greater than the short side length Wa.

Referring to FIG. 21 and FIG. 22, the long side length Wc of the bank hole OP may be larger than, smaller than, or similar to the diameter DD of the spacer CS overlapping the bank hole OP, and the short side length Wa of the bank hole OP may be smaller than the radius DD/2 of the spacer CS overlapping the bank hole OP.

Referring to FIGS. 23 and 24, the bank hole OP may have various planar shapes.

*For example, as shown in (a) of FIG. 23, the planar shape of the bank hole OP is approximately rectangular, and the length of the long side of the bank hole OP is approximately similar to the diameter of the spacer CS overlapping the bank hole OP.

As shown in (b) of FIG. 23, the planar shape of the bank hole OP may have a generally rectangular shape and include a circular portion midway.

As shown in (c) of FIG. 23, the planar shape of the bank hole OP may be elliptical, and the long side length may be greater than the diameter of the spacer CS overlapping the bank hole OP.

As shown in (d) of FIG. 23, the planar shape of the bank hole OP may be an elliptical shape, and the long side length may be substantially similar to the diameter of the spacer CS overlapping the bank hole OP.

As shown in (e) of FIG. 23, the planar shape of the bank hole OP may be elliptical, and the long side length may be smaller than the diameter of the spacer CS overlapping the bank hole OP.

As shown in (f) of FIG. 23, the planar shape of the bank hole OP may be circular, with a diameter that is smaller than the diameter of the spacer CS overlapping the bank hole OP.

As shown in (g) of FIG. 23, the planar shape of the bank hole OP may be a polygon, for example, a hexagon, and the long side length may be smaller than the diameter of the spacer CS overlapping the bank hole OP.

As shown in (h) of FIG. 23, the planar shape of the bank hole OP may be a polygon, for example, a rectangle, and the long side length may be smaller than the diameter of the spacer CS overlapping the bank hole OP.

For example, as shown in (a) of FIG. 24, the planar shape of the bank hole OP can have a shape where two or more rectangles intersect, and the length of the long side of each rectangular portion can be larger than the diameter of the spacer CS overlapping with the bank hole OP.

As shown in (b) of FIG. 24, the planar shape of the bank hole OP can have a form where two or more rectangles intersect, and the length of the long side of each rectangular portion can be similar to the diameter of the spacer CS overlapping the bank hole OP.

As shown in (c) of FIG. 24, the planar shape of the bank hole OP may have a shape in which two or more rectangles intersect, and the length of the long side of at least one rectangular portion is the length of the spacer CS overlapping the bank hole OP diameter, and the length of the long side of the remaining rectangular portion may be smaller than or similar to the diameter of the spacer CS.

As shown in (d) of FIG. 24, the planar shape of the bank hole OP is similar to that of the bank hole OP of (a) of FIG. 24, but may further include a circular portion in the center.

As shown in (e) of FIG. 24, the planar shape of the bank hole OP is similar to that of the bank hole OP of (b) of FIG. 24, but may further include a circular portion in the center.

As shown in (f) of FIG. 24, the planar shape of the bank hole OP is similar to that of the bank hole OP of (c) of FIG. 24, but may further include a circular portion in the center.

As in (g) of FIG. 24, the planar shape of the bank hole OP can have a shape where two or more rectangles meet near the center of the spacer CS with the long sides extending out from the center, and the length of the long side of each rectangular portion can be greater than the radius of the spacer CS that overlaps the bank hole OP.

As shown in (h) of FIG. 24, the planar shape of the bank hole OP may have a shape in which two or more rectangles meet near the center of the spacer CS with the long sides extending out from the center, and the length of the long side of each rectangular portion is the length of the spacer CS overlapping the bank hole OP, it can be similar to a radius.

As shown in (i) of FIG. 24, the planar shape of the bank hole OP is similar to that of the bank hole OP of (g) of FIG. 24, but may further include a circular portion in the middle.

As shown in (j) of FIG. 24, the planar shape of the bank hole OP is similar to that of the bank hole OP of (h) of FIG. 24, but may further include a circular portion in the middle.

In (b) of FIGS. 23 and 24, dotted lines at the boundary between unit shapes (circles, rectangles) are shown for convenience of explanation of the planar shape of the bank hole OP, but each bank hole OP shown is not a plurality of holes, a hole formed integrally may be achieved.

The above examples of the planar shape of the bank hole OP are not intended to be exhaustive, and variations in shape are covered by this disclosure.

Although the embodiments of the present disclosure are described in detail above, the scope of the present disclosure is not limited thereto, and various modifications and improvements of those skilled in the art using the basic concepts of the present invention defined in the following claims are also included in the scope of the present disclosure.

What is claimed is:

1. A display device, comprising:
a plurality of light emitting regions and a non-light emitting region positioned between adjacent light emitting regions; and
a color conversion unit overlapping the display unit and including a bank layer and a spacer,
wherein the bank layer has an opening corresponding to the light emitting region and a bank hole corresponding to the non-light emitting region,
the bank hole overlaps the spacer on a plane, and
at least a portion of an edge of the bank layer around the bank hole comprises a low liquid repellent portion having lower liquid repellency than a remaining surface of the bank layer.

2. The display device of claim 1, wherein
the low liquid repellent portion is formed along a periphery of the bank hole.

3. The display device of claim 1, wherein
a color conversion layer is positioned in the opening, and
a material layer having a material included in the color conversion layer is located in the bank hole.

4. The display device of claim 3, wherein
a thickness of the material layer is smaller than a thickness of the color conversion layer.

5. The display device of claim 4, wherein
the material layer comprises semiconductor nanocrystals.

6. The display device of claim 1, wherein
the display unit comprises a pixel insulating layer having a pixel opening defining the light emitting region and overlapping the non-light emitting region, and
the color conversion unit comprises a substrate and a plurality of color filters positioned between the substrate and the bank layer.

7. The display device of claim 6, wherein
the spacer comprises a portion positioned inside the bank hole and a portion positioned outside the bank hole and covering the bank hole.

8. The display device of claim 7, wherein
the bank layer is positioned between the spacer and the plurality of color filters, and further comprises
a filling layer positioned between the bank layer and the display unit.

9. The display device of claim 6, wherein
the spacer is spaced apart from the bank hole.

10. The display device of claim 9, wherein
the spacer is positioned between the bank layer and the plurality of color filters, and
a filling layer is positioned between the bank layer and the plurality of color filters.

11. The display device of claim 10, wherein
the display unit further comprises a light emitting device and an encapsulation portion covering the light emitting device, and
the bank layer is formed on the encapsulation portion.

12. The display device of claim 1, wherein
the low liquid repellent portion forms an inclined surface or a concave portion along a peripheral surface of the bank layer.

13. The display device of claim 1, wherein
the bank hole has a long side in a plan view and a short side shorter than the long side, and
a length of the short side of the bank hole is smaller than a radius of the spacer overlapping the bank hole.

14. A display device, comprising:
a display unit having a plurality of light emitting regions and a non-light emitting region positioned between adjacent light-emitting regions; and
a color conversion unit overlapping the display unit and including a bank layer and a spacer,
wherein the bank layer has an opening corresponding to the light emitting region and a bank hole corresponding to the non-light emitting region,
the bank hole overlaps the spacer on a plane,
the bank hole has a long side in a plan view and a short side shorter than the long side, and
a length of the short side of the bank hole is smaller than a radius of the spacer overlapping the bank hole.

15. The display device of claim 14, wherein
the length of the long side of the bank hole is longer than a diameter of the overlapping spacer.

16. The display device of claim 14, wherein
an edge of the bank layer around the bank hole comprises a low liquid repellent portion having a lower liquid repellency than a remaining surface of the bank layer.

17. The display device of claim 16, wherein
the low liquid repellent portion is formed along a periphery of the bank hole.

18. A method for manufacturing a display device, comprising:
forming a bank layer having a plurality of openings and a plurality of bank holes by patterning an organic material layer on a substrate;
forming a color conversion layer and a transmission layer in the plurality of openings; and
forming a spacer overlapping the bank hole,
wherein the forming the bank layer comprises forming a low liquid repellent portion on an edge of the bank layer around the bank hole, wherein the low liquid repellent has a lower liquid repellency than a remaining surface of the bank layer.

19. The method for manufacturing a display device of claim 18, wherein
the forming of the bank layer comprises forming a first portion corresponding to the bank hole, a second portion having transmittance opposite to that of the first portion, and a second portion disposed between the first portion and the second portion and having transmissivity and exposing the bank layer to light through an exposure mask having a third portion.

20. The method for manufacturing a display device of claim 19, wherein
the third portion comprises a translucent portion or a slit.
